(19) United States
(12) Patent Application Publication
(10) Pub. No.: US 2003/0118091 A1
(43) Pub. Date: Jun. 26, 2003

(54) System and method for reducing power dissipation for DSL circuits

(75) Inventor: Kevin Golka, Kanata (CA)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Catena Networks, Inc., Redwood Shores, CA

(21) Appl. No.: 10/298,248

(22) Filed: Nov. 14, 2002

(30) Foreign Application Priority Data
Nov. 14, 2001 (CA) 2,361,967

(51) Int. Cl. H04B 1/38; H03K 3/00; H03B 1/00; H04M 11/00; H04L 5/16

(52) U.S. Cl. 375/222; 379/93.01; 327/108

(57) ABSTRACT

In accordance with an aspect of the present invention, there is provided a line card for providing data communication with a plurality of lines. The line card includes a plurality of modems and a plurality of switches. The modems determine a required headroom on each of the lines. Each of the switches selectively applies one of a plurality of available power supply voltages to a line driver on a corresponding one of the lines in accordance with the required headroom. A lowest voltage available that can maintain the required headroom is applied to each of the line drivers on a per-line basis for reducing power dissipation at the line card.

### CROSS-REFERENCES TO RELATED APPLICATIONS

Not applicable

### STATEMENT AS TO RIGHTS TO INVENTIONS MADE UNDER FEDERALLY SPONSORED RESEARCH OR DEVELOPMENT

Not applicable

### REFERENCE TO A “SEQUENCE LISTING,” A TABLE, OR A COMPUTER PROGRAM LISTING APPENDIX SUBMITTED ON A COMPACT DISK.

Not applicable

### BACKGROUND OF THE INVENTION

The present invention relates generally to Digital Subscriber Loop (DSL) technology, and specifically to a circuit for reducing power dissipation by the DSL technology.

Remote access and retrieval of data is becoming increasingly popular in data communication. The proliferation of the Internet has provided a vast network of information that is available to the general public. As the Internet grows and technology advances, this information is becoming increasingly voluminous and the details are become increasingly intricate. What used to be mainly text information has grown to include still and moving images as well as sound. The increase in the volume of information to be transferred has presented a need for a high-speed Internet connection, since traditional telephone modems communicate at speeds too slow for efficient communication.

One proposal for high-speed communication is the introduction of Digital Subscriber Line (DSL) technology. The various DSL technologies include ADSL, HDSL, SDSL, SHDSL and ISDN BRI DSL systems. One of the most attractive features of DSL is that it is implemented using an infrastructure that already exists. DSL shares copper twisted pair lines typically used for telephone communication. However, only a small portion of the available bandwidth of the twisted pair line (0 to 4 kHz) is used for Plain Old Telephone Service (POTS). DSL takes advantage of the available frequency spectrum from 4 kHz to approximately 1.1 MHz for transmitting data.

“Downstream” is a term commonly used to describe communication in the direction of a central office to a subscriber. A transmitter uses a predefined power level for transmitting the downstream signal. Typically, power supply rails are fixed to allow the highest signal voltage to pass through line drivers without distortion. In these cases, the power supply rails are often fixed to higher voltage levels than are actually needed for everyday use.

Signal voltage headroom, required for DSL on a transmission loop, is dependent largely upon the loop length. That is, shorter loops do not require voltage rails as high as long loops. Setting the power supply rails to voltages high enough to work for long loops incurs higher current consumption and higher thermal dissipation than is needed for short loops. If the rails are set lower to reduce current consumption and thermal dissipation, then they will not be capable of handling the signal voltage requirements for long loops.

It is preferable to use a minimum amount of power. Lower current consumption reduces operating costs. It also allows for longer operation while operating on batteries during ac-mains failure. Reduced thermal dissipation lowers component and system temperatures. Lower temperatures generally improve reliability of all of the system components.

Thus, there is a need for a system that uses minimal power and is capable of handling the signal voltage requirements for long loops.

### BRIEF SUMMARY OF THE INVENTION

In accordance with an aspect of the present invention, there is provided a line card for providing data communication with a plurality of lines. The line card includes a plurality of modems and a plurality of switches. The modems determine a required headroom on each of the lines. Each of the switches selectively applies one of a plurality of available power supply voltages to a line driver on a corresponding one of the lines in accordance with the required headroom. A lowest voltage available that can maintain the required headroom is applied to each of the line drivers on a per-line basis for reducing power dissipation at the line card.

One advantage of the present invention is the reduction of current consumption and thermal dissipation while maintaining necessary headroom for telecommunication and data signals on the transmission loops.

### BRIEF DESCRIPTION OF THE DRAWINGS

An embodiment of the invention will now be described by way of example only with reference to the following drawings in which:

FIG. 1 is a high-level schematic diagram of a switching circuit in accordance with an embodiment of the present invention; and

FIG. 2 is a block diagram of a line card according to an embodiment of the present invention.

### DETAILED DESCRIPTION OF THE INVENTION

For convenience, like numerals in the description refer to like structures in the drawings. An embodiment of the invention provides a lower voltage power rail for short loops than it does for long loops. Reducing power supply voltage rails based on signal requirements helps reduce current consumption and thermal dissipation while maintaining necessary headroom for telecommunication and data signals on transmission loops. This in itself, however, is inadequate because in a system that uses multi-line cards, it is problematic to select only one power supply rail for the whole card. Thus, coordination of short loops on one card and long loops on another card would be required. Such coordination adds complexity and cost to provisioning and administering lines in a telecommunication or data system.

However, by controlling the power supply rail selection on a per-line basis, it is possible to realize benefits of using a lower power supply rail, while providing a higher power supply rail only when and where it is necessary.

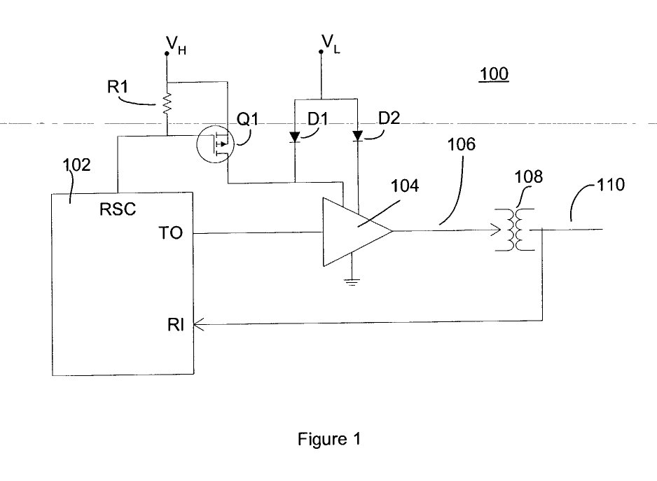

Referring to FIG. 1, a schematic diagram of a switching circuit according to an embodiment of the present invention is illustrated generally by numeral 100. The circuit 100 includes a POTS and DSL modem 102, a resistor R1, a transistor Q1, first and second diodes D1 and D2, a line driver 104, a transformer 108, a high power supply rail V_{H}, and a low power supply rail V_{L}. The line driver 104 has an input, output, ground connection, low power supply pin, and high power supply pin. The modem 102 includes a transmit output TO, receive input RI, and rail selection control output RSC.

The TO of the modem 102 is coupled to the input of the line driver 104. The output of the line driver 104 is coupled to the transformer 108, which couples downstream output from the line driver 102 to a subscriber loop 110. The subscriber loop 110 is also coupled to the RI of the modem 102.

The high power supply rail V_{H} is coupled to a source of the transistor Q1 and to a gate of the transistor Q1 via the resistor R1. The RSC output is also coupled to the gate of the transistor Q1. A drain of the transistor Q1 is coupled to the high power supply pin of the line driver 104. The low power supply rail V_{L} is coupled to the high power supply pin of the line driver 104 via the first diode D1 and to the low power supply pin of the line driver 104 via the second diode D2. A switch 100 as described above is provided for each line on the card.

The operation of the circuit 100 is described as follows. The modem 102 determines when high voltage power supply rails are required. Various methods can be used to do this. In the case of DSL transmission in the present embodiment, Digital Signal Processing (DSP) algorithms are used during the initial training phase of the loops to determine the optimum transmission settings. These algorithms are standard in the art. In the normal training process of the modem 102, information regarding the required transmit power is required. The required transmit power is compared against a predefined threshold. If the required transmit power is above the threshold, the higher voltage power supply rail is used. Conversely, if the required transmit power falls below the threshold, the lower voltage power supply rail is used.

Once the selection is made, a signal is sent to the per-line rail-switch transistor Q1 to select either the high or the low power-supply rail for that particular line. For example, if during the training session it is determined that the headroom required by the line driver is low, the lower power supply can be used. The RSC output for the corresponding line is set to a high voltage. Since there is a high voltage at both the gate and source of the transistor Q1, the transistor Q1 is turned off. Therefore, the input to the high power supply pin is that of the low power supply rail reduced by the voltage drop across the first diode D1. The input to the low power supply pin is that of the low power supply rail reduced by the voltage drop across the second diode D2. The second diode D2 is used to ensure that the voltage level at the low power supply pin is not higher than the voltage level at the high power supply pin.

However, if during the training session it is determined that the headroom required by the line driver is high, the higher power supply should be used. The RSC output for the corresponding line is set to a low voltage. As a result, the voltage at the gate of transistor Q1 is low, turning on the transistor Q1. As the transistor Q1 begins to conduct, the first diode D1 becomes reverse-biased, effectively switching the voltage at the high power supply pin from the lower voltage power rail to the higher voltage power rail. The input to the low power supply pin is still that of the low power supply rail reduced by the voltage drop across the second diode D2.

This smooth transition can allow for changing rails “on-the-fly”. That is, it is possible to trigger a switch between power rails in the middle of a transmission if it is deemed necessary. The smooth transition ensures that there is minimum impact to any data transmission that may be in progress.

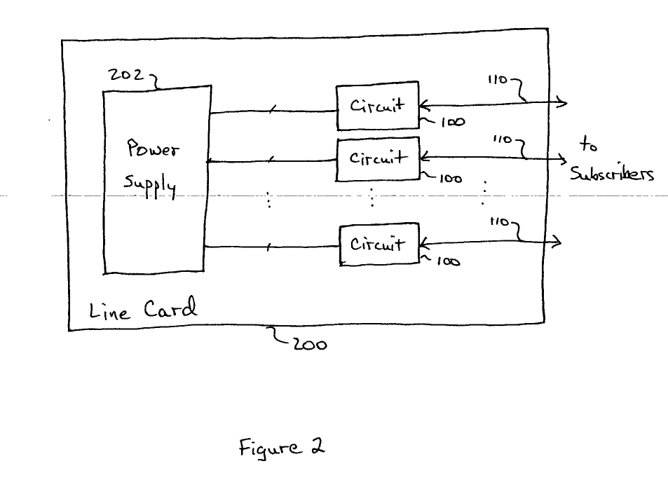

FIG. 2 is a block diagram of a line card 200 according to an embodiment of the present invention. The line card 200 includes a power supply 202, a number of switching circuits 100, and a number of lines 110 that connect to subscribers. The power supply provides the high power supply rail V_{H} and the low power supply rail V_{L} to the switching circuits 100. The line card 200 also includes data transmission paths that are not shown. Such a line card 200 can save power and can have an improved reliability as compared to a line card without the switching circuits 100.

In alternate embodiments, it is possible to use more than two supply power rail levels. For example, three supply power rail levels can be used. In such a case, two predefined thresholds are used for determining which of the power rail levels are to be used. If the signal headroom is below a first threshold, the lowest power rail level is used. If the signal headroom is between the first threshold and a second threshold, a middle power rail level is used. If the signal headroom is above the second threshold, the highest power rail level is used. A circuit for implementing such a switch will be apparent to a person skilled in the art based on the description provided herein.

Although the invention has been described with reference to certain specific embodiments, various modifications thereof will be apparent to those skilled in the art without departing from the spirit and scope of the invention as outlined in the claims appended hereto.

What is claimed is:

1. A line card for providing data communication with a plurality of lines, said line card including:
a plurality of line drivers coupled to said plurality of lines;
a plurality of modems, coupled to said plurality of line drivers, for identifying a required headroom on each of said plurality of lines; and
a plurality of switches, coupled to said plurality of modems, each for selectively applying one of a plurality of power supply voltages to a corresponding one of said plurality of line drivers associated with a corresponding one of said plurality of lines in accordance with said required headroom,
wherein a lowest voltage available that can maintain said required headroom is applied to each of said plurality of line drivers on a per-line basis for reducing power dissipation at said line card.

2. A line card as defined in claim 1, wherein each of said plurality of switches comprises:
a transistor coupled between a higher one of said plurality of power supply voltages and a high power supply pin of one of said plurality of line drivers.

3. A line card as defined in claim 2, further comprising:
a diode coupled between a lower one of said plurality of power supply voltages and said high power supply pin of one of said plurality of line drivers.

4. A line card as defined in claim 3, wherein said transistor is turned on for applying said higher one of said plurality of power supply voltages to said high power supply pin of one of said plurality of line drivers.

5. A line card as defined in claim 3, wherein said transistor is turned off for applying said lower one of said plurality of power supply voltages to said high power supply pin of one of said plurality of line drivers.

6. A line card as defined in claim 3, wherein said transistor is gated by a signal from one of said plurality of modems in accordance with said identified headroom.

7. A line card as defined in claim 6, wherein one of said plurality of modems determines said required headroom.

8. A line card as defined in claim 1, wherein said plurality of modems further communicate data with said plurality of lines, and wherein said plurality of switches are configured to smoothly transition between said plurality of power supply voltages during communication of said data.
